(19) United States
(12) Patent Application Publication
(10) Pub. No.: US 2022/0055914 A1
(43) Pub. Date: Feb. 24, 2022

(54) METHOD FOR PREPARING FLAKY IRON OXIDE

(71) Applicant: Fujian Agriculture and Forestry University, Fuzhou City (CN)

(72) Inventors: Zhanhui Yuan, Fuzhou City (CN); Qixing Zhang, Fuzhou City (CN); Weiming Zhou, Fuzhou City (CN); Mingxin Zhang, Fuzhou City (CN); Chuanting You, Fuzhou City (CN); Shichang Sun, Fuzhou City (CN)

(21) Appl. No.: 17/518,878

(22) Filed: Nov. 4, 2021

Related U.S. Application Data
(62) Division of application No. 16/870,023, filed on May 8, 2020.

(30) Foreign Application Priority Data
May 10, 2019 (CN) 201910386670.4

(51) Int. Cl. C01G 49/06; C23C 14/08; C23C 14/34; C23C 14/58

(52) U.S. Cl. CPC C01G 49/06; C23C 14/085; C01P 2004/20; C23C 14/5806; C23C 14/34

(57) ABSTRACT

The invention discloses a method for preparing a flaky iron oxide. The flaky iron oxide is obtained through a vacuum coating machine. The vacuum coating machine includes a vacuum pump, a vacuum pipeline arrangement, a vacuum coating chamber, a flaky iron oxide supporting chamber and an electrical discharging gas inlet. High-energy particles generated by an iron oxide target are deposited on the surface of the conveying belt; and then the flaky iron oxide on a conveying belt is stripped and calcined to obtain the flaky iron oxide with bright color. By means of the method, vacuum sputtering time can be controlled to prepare the flaky iron oxide with various diameter-to-thickness ratios, and pollution caused by a traditional chemical deposition preparation method can be avoided. The preparation method is simple and environment-friendly. Due to the adoption of roller transmission, the production efficiency is improved.

### CROSS REFERENCE TO RELATED APPLICATIONS

This application is a Divisional of U.S. patent application Ser. No. 16/870,023 filed May 8, 2020, which claims the benefit of Chinese Patent Application No. 201910386670.4 filed to the State Intellectual Property Office on May 10, 2019 and entitled “METHOD FOR PREPARING FLAKY IRON OXIDE”, which is incorporated herein by reference in its entirety.

### TECHNICAL FIELD

The invention relates to the field of inorganic powder materials, in particular to a method for preparing a flaky iron oxide.

### BACKGROUND

As an inorganic pigment, the flaky iron oxide has a unique flake structure, thereby being glossy, colorful, and widely applied to fields like coatings, pearlescent pigments, and cosmetics. However, the widely-used flaky iron oxide is a natural micaceous iron oxide. A flaky iron oxide finished product obtained by crushing micaceous iron oxide ore is high in impurity content and prone to surface scratching, thereby being worse in brightness, color and gloss, and failing to meet requirements for high-grade pigments. In view of this, it is significant to have a method for developing an artificially synthesized flaky iron oxide. According to the patent CN 101913657 A, a precursor solution is prepared in dilute sulfuric acid by co-dissolving ferric trichloride hexahydrate, composite molten salt and an additive, and is then dried at the temperature of 100-150° C. for 24-36 hours until there is no water; the dried precursor solution is ground to obtain precursor powder; the precursor powder is calcined at the temperature of 900-1200° C. for 2-6 hours and is finally stirred in a water bath, washed, filtered and dried to obtain the flaky iron oxide product. The method is complicated to implement. Specifically, the flaky iron oxide is prone to surface damage in the grinding process, thereby reducing pigment quality. Pearlescent pigments and cosmetics have a desirable decoration effect only when the ratio of particle size to grain diameter of the flaky iron oxide therein meets certain requirements. As a superior choice, according to the patent EP0191292A2, iron oxide applied to cosmetics shall be 10-60 micrometers in average particle size and 0.2-1 micrometers in thickness.

At present, iron oxide can be synthesized mainly through a hydrothermal method, a high-temperature molten salt method and a gas phase method. According to the patents U.S. Pat. No. 3,987,156, GB1333788, EP0416648 and CN1944274A, hydrothermal methods are used for preparing iron oxide, where ferrous sulfate is used as a raw material, an oxidizing agent is used to oxidize a divalent iron source into ferric iron, and then the ferric iron reacts with alkali to obtain the synthesized flaky iron oxide in a high-pressure reaction kettle. However, this method has high requirements for pressure resistance and acid and alkali resistance of reaction equipment, thereby being inconvenient to apply to industrial production. According to the patent U.S. Pat. No. 3,864,463, a vapor deposition method is used to prepare a flaky iron oxide, where ferric trichloride vapor and oxygen-containing gas are subjected to contact reaction at 400-750° C. to be deposited on the surface of a fixed bed to obtain the flaky iron oxide. The method cannot easily control the thickness of a film, the efficiency is low, and the diameter-to-thickness ratios of finished products differ. According to the patent EP0307486 A2, a high-temperature molten salt method is used to mix a trivalent iron source substance with an alkali metal substance, and the mixture in a high-temperature molten state is oxidized with oxygen to obtain the flaky iron oxide. According to the patent U.S. Pat. No. 4,676,838, an additive is added to activate iron oxide seed crystals, and a prepared product is small in particle size and has the diameter-to-thickness ratio of 20-100. All the methods mentioned above to prepare the flaky iron oxide involve chemical reagents which can pollute the environment to a certain extent, and the preparation process is complex. At present, there are few reports of applying a vacuum sputtering method to prepare a flaky iron oxide. However, this method is economical, environment-friendly, and capable of embodying the development concept of green production.

### SUMMARY

The invention provides a method for preparing a flaky iron oxide. The method complies with the concept of green development, and the flaky iron oxide with uniform thickness prepared according to the method can meet the requirements of high-grade pigments.

To achieve the above purpose, the present invention provides the following technical solutions.

The present invention provides a method for preparing a flaky iron oxide, where the flaky iron oxide is obtained by a vacuum coating machine; the vacuum coating machine includes a vacuum pump, a vacuum pipeline arrangement, a vacuum coating chamber, a flaky iron oxide supporting chamber and an electrical discharging gas inlet; the flaky iron oxide supporting chamber is located below the vacuum coating chamber; the vacuum coating chamber includes a shell; the bottom of the vacuum coating chamber is provided with a target mounting platform; a flaky iron oxide receiving disc connected with the flaky iron oxide supporting chamber is arranged above the target mounting platform; a plurality of large rollers and small rollers are uniformly arranged in the vacuum coating chamber and are connected with each other through a conveying belt; heating equipment is arranged on the two sides of the vacuum coating chamber; and scrapers for stripping flaky iron oxides are symmetrically arranged in the middle of the vacuum coating chamber and are controlled by scraper controllers.

Further, the vacuum coating machine is vertical or horizontal, and preferably vertical for ease of operations.

Further, the conveying belt is a plastic film, flexible metal film, or rubber film conveying belt.

Further, the plastic film conveying belt is specifically a high-temperature-resistant polytetrafluoroethylene plastic film, Teflon film or polyimide plastic film conveying belt, the metal film conveying belt is a stainless steel film conveying belt, and the rubber film conveying belt is a fluororubber film conveying belt.

Further, the target mounting platform of the iron oxide is located at the center line of the vacuum coating chamber to ensure coating uniformity.

Further, the method specifically includes the following steps of:

(1) mounting the iron oxide target on the target mounting platform in the vacuum coating chamber, cleaning the conveying belt, controlling the sputtering direction of the target, and ensuring that iron oxide particles are deposited on the surface of the conveying belt;

(2) closing the vacuum coating chamber, starting the vacuum pump, and vacuumizing the vacuum coating chamber;

(3) starting the heating equipment, heating the vacuum coating chamber to a certain temperature for exhausting, and ensuring the vacuum degree of the vacuum coating chamber;

(4) introducing ionized gas, performing electrical discharging, exciting the iron oxide target to generate high-energy particles, and depositing the high-energy particles on the surface of the conveying belt;

(5) starting the large rollers and the small rollers to enable the surface of the conveying belt to be uniformly plated with the flaky iron oxide, performing exhausting after coating is completed, then starting the scraper controllers to strip the flaky iron oxide on the conveying belt into the flaky iron oxide receiving disc by the scrapers; and

(6) increasing the temperature in the vacuum coating chamber, calcining the flaky iron oxide in the flaky iron oxide receiving disc, and then introducing the processed flaky iron oxide into the flaky iron oxide supporting chamber below the vacuum coating chamber for collection.

Further, the iron oxide target in the step (1) is blocky or granulous and is prepared by a tablet press.

Further, the vacuum degree of vacuumizing in the step (2) is 10⁻⁴-10⁻¹ Pa.

Further, the heating temperature in the step (3) is 200-400° C.

Further, the ionized gas in the step (4) is an inert gas, and the gas is introduced at 0.1-0.5 ml/min.

Further, the calcination in the step (5) is conducted at 600-700° C. for 10-15 minutes.

The present invention has the following beneficial effects:

1. The method complies with the environment-friendly production concept, thereby avoiding environmental pollution caused by chemical synthesis methods.

2. The thickness of the flaky iron oxide can be well controlled to ensure the consistency of the diameter-to-thickness ratio of the iron oxide.

3. Continuous coating production can be carried out through roller transmission to improve the production efficiency.

### BRIEF DESCRIPTION OF DRAWINGS

FIG. 1 is a schematic structural view of a vacuum coating machine of the present invention;

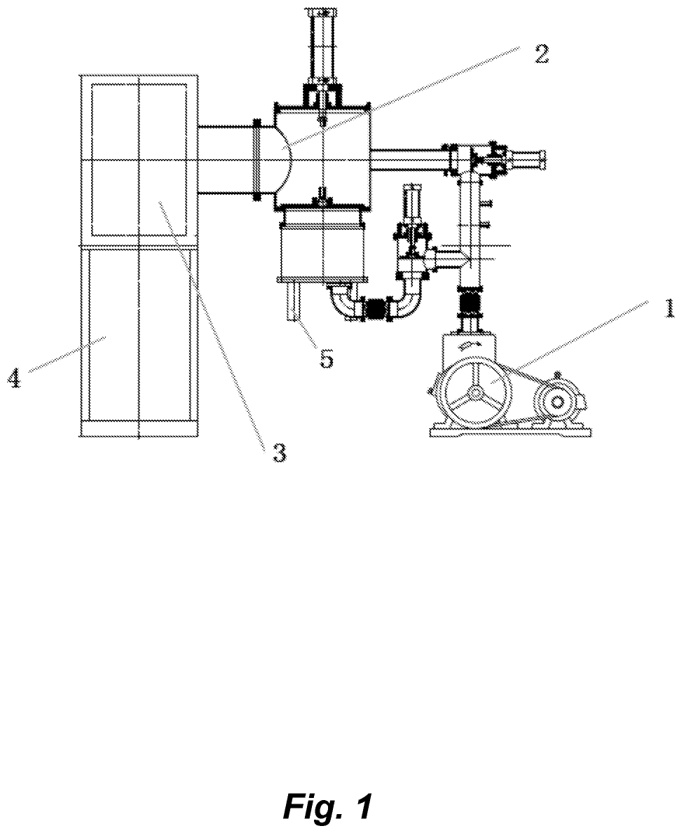

FIG. 2 is a schematic structural view of a vacuum coating chamber;

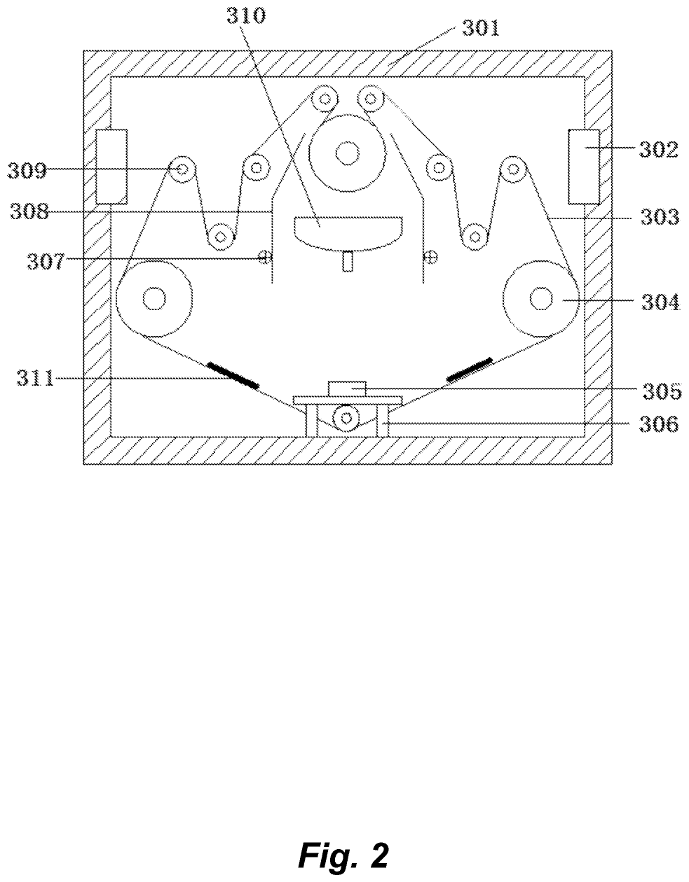

Numeral References: 1. vacuum pump; 2. vacuum pipeline arrangement; 3. vacuum coating chamber; 301. shell; 302. heating equipment; 303. conveying belt; 304. large roller; 305. iron oxide target; 306. target mounting platform; 307. scraper controller; 308. scraper; 309. small roller; 310. flaky iron oxide receiving disc; 311. flaky iron oxide; 4. flaky iron oxide supporting chamber; 5. electrical discharging gas inlet.

### DETAILED DESCRIPTION

The following describes the preferred embodiment of the present invention in more detail to make the advantages and features of the present invention more readily understood by those skilled in the art and further to define the protection scope of the present invention.

### EXAMPLE 1

Disclosed is a method for preparing a flaky iron oxide. The flaky iron oxide is obtained by a vacuum coating machine. As shown in the accompanying drawings, the vacuum coating machine includes a vacuum pump 1, a vacuum pipeline arrangement 2, a vacuum coating chamber 3, a flaky iron oxide supporting chamber 4 and an electrical discharging gas inlet 5; the flaky iron oxide supporting chamber 4 is located below the vacuum coating chamber 3; the vacuum coating chamber 3 includes a shell 301; the bottom of the vacuum coating chamber 3 is provided with a target mounting platform 306; a flaky iron oxide receiving disc 310 connected with the flaky iron oxide supporting chamber 4 is arranged above the target mounting platform 306; a plurality of large rollers 304 and small rollers 309 are uniformly arranged in the vacuum coating chamber 3 and are connected with each other through a conveying belt 303; heating equipment 302 is arranged on the two sides of the vacuum coating chamber; and scrapers 308 for stripping flaky iron oxides 311 are symmetrically arranged in the middle of the vacuum coating chamber 3 and are controlled by scraper controllers 307.

In this example, the vacuum coating machine is vertical and convenient to operate.

In this example, a fluororubber film conveying belt is used as the conveying belt.

In this example, the target mounting platform of the iron oxide is located at the center line of the vacuum coating chamber to ensure coating uniformity.

The method for preparing the flaky iron oxide includes the following steps:

(1) iron oxide powder is pressed to form the shape of a cake, and is then mounted on the target mounting platform 306 of the vacuum coating chamber 3, the surface of the conveying belt 303 is cleaned by using ethanol, and the sputtering direction of a target is controlled, to ensure that iron oxide particles are deposited on the surface of the conveying belt 303;

(2) the vacuum coating chamber 3 is closed, the vacuum pump 1 is started, and the vacuum coating chamber 3 is vacuumized;

(3) when the vacuum degree of the vacuum coating chamber 3 reaches 6.2*10⁻³ Pa, the heating equipment 302 is started, and the vacuum coating chamber 3 is heated to 200° C. for exhausting to ensure the vacuum degree of the vacuum coating chamber 3;

(4) argon is introduced at the rate of 0.3 ml/min, and electrical discharging is performed to excite the iron oxide target to generate high-energy particles to be deposited on the surface of the conveying belt 303;

(5) the large rollers and the small rollers are started to enable the surface of the conveying belt 303 to be uniformly plated with the flaky iron oxide 311, exhausting is performed after coating is completed, then the scraper controllers 308 are started, and the flaky iron oxide 311 on the conveying belt 303 is stripped into the flaky iron oxide receiving disc 310 by the scrapers 308; and

(6) the temperature in the vacuum coating chamber 3 is increased to 650° C., the flaky iron oxide 311 in the flaky iron oxide receiving disc 310 is calcined for 10 minutes, and then the processed flaky iron oxide 311 is introduced into the flaky iron oxide supporting chamber 4 below the vacuum coating chamber 3 for collection.

The flaky iron oxide prepared by the method is uniform in thickness, good in transparency, smooth in surface and rich in metal luster, and can meet requirements of high-grade cosmetics and high-grade pearlescent pigments.

The foregoing is an example of the present invention and does not constitute a limitation on the scope of the present invention. Any equivalent structure or equivalent process change made by using the description of the present invention, or direct or indirect application thereof in other related technical fields, shall still fall in the protection scope of the patent of the present invention.

What is claimed is:

1. A vacuum coating machine for preparing a flaky iron oxide, wherein the flaky iron oxide is obtained by the vacuum coating machine; the vacuum coating machine comprising:
a vacuum pump;
a vacuum pipeline arrangement;
a vacuum coating chamber comprising a shell, and a bottom of the vacuum coating chamber being provided with a target mounting platform;
a flaky iron oxide supporting chamber located below the vacuum coating chamber; and
an electrical discharging gas inlet;
wherein a flaky iron oxide receiving disc connected with the flaky iron oxide supporting chamber is arranged above the target mounting platform; a plurality of large rollers and small rollers are uniformly arranged in the vacuum coating chamber and are connected with each other through a conveying belt; heating equipment is arranged on the two sides of the vacuum coating chamber; and
scrapers for stripping flaky iron oxides are symmetrically arranged in the middle of the vacuum coating chamber and are controlled by scraper controllers.

2. The vacuum coating machine for preparing the flaky iron oxide according to claim 1, wherein the vacuum coating machine is vertical or horizontal.

3. The vacuum coating machine for preparing the flaky iron oxide according to claim 1, wherein the conveying belt is a plastic film, flexible metal film, or rubber film conveying belt.

4. The vacuum coating machine for preparing the flaky iron oxide according to claim 3, wherein the plastic film conveying belt is specifically a high-temperature-resistant polytetrafluoroethylene plastic film, Teflon film or polyimide plastic film conveying belt, the flexible metal film conveying belt is a stainless steel film conveying belt, and the rubber film conveying belt is a fluororubber film conveying belt.
